(19) United States
(12) Patent Application Publication
(10) Pub. No.: US 2021/0351097 A1
(43) Pub. Date: Nov. 11, 2021

(54) METHOD FOR FABRICATING ELECTRONIC STRUCTURE WITH CONDUCTIVE ELEMENTS ARRANGED FOR HEATING PROCESS

(71) Applicant: Siliconware Precision Industries Co., Ltd., Taichung (TW)

(72) Inventors: Chih-Chiang He, Taichung (TW); Yu-Wei Yeh, Taichung (TW); Chia-Yang Chen, Taichung (TW); Chih-Yi Liao, Taichung (TW); Chih-Hsien Chiu, Taichung (TW); Chang-Chao Su, Taichung (TW)

(21) Appl. No.: 17/241,199

(22) Filed: Apr. 27, 2021

Related U.S. Application Data
(62) Division of application No. 16/793,667, filed on Feb. 18, 2020, now abandoned.
Application No. 16/793,667 is a continuation-in-part of application No. 16/460,766, filed on Jul. 2, 2019, now abandoned.

(30) Foreign Application Priority Data
Dec. 24, 2019 (TW) 108147409

(51) Int. Cl. H01L 23/31; H01L 23/00; H01L 21/56; H01L 23/498; H01L 23/538; H01L 21/768

(52) U.S. Cl. CPC H01L 23/3128; H01L 24/13; H01L 24/81; H01L 21/56; H01L 2224/11849; H01L 23/5383; H01L 24/11; H01L 21/76882; H01L 23/49816

(57) ABSTRACT

An electronic structure and a method for fabricating the same are provided. An electronic component and conductive elements are disposed on a carrier. An encapsulation layer encapsulates the electronic component and the conductive elements. The encapsulation layer has concave portions corresponding in position to the conductive elements. Each of the conductive elements is in no contact with corresponding one of the concave portions.

### CROSS-REFERENCE TO RELATED APPLICATIONS

This application is a divisional of U.S. Ser. No. 16/793,667, filed on Feb. 18, 2020, which is a continuation-in-part of U.S. Ser. No. 16/460,766, filed on Jul. 2, 2019, and claims priority to Taiwanese Application Serial No. 108147409, filed on Dec. 24, 2019. The entirety of the applications are hereby incorporated by reference herein and made a part of this specification.

### BACKGROUND

### 1. Technical Field

The present disclosure relates to semiconductor packaging processes, and, more particularly, to an electronic structure and a method for fabricating the same.

### 2. Description of the Prior Art

With the rapid development of portable electronic products, a variety of related products are demanded to be compact and low-profiled. Accordingly, various types of semiconductor packaging structures come to the market, in order for the electronic products to meet the compactness and low profile requirements.

FIG. 1 is a cross-sectional view of a semiconductor packaging structure 1 according to the prior art. The semiconductor packaging structure 1 comprises a substrate 10, semiconductor elements 11 and passive elements 11′ disposed on upper and lower sides of the substrate 10, and an encapsulation compound 14 encapsulating the semiconductor elements 11 and the passive elements 11′. Contacts (I/O) of the substrate 10 are formed by a through mold via (TMV) method and exposed from holes 140a of the encapsulation compound 14. The semiconductor packaging structure 1 further comprises a plurality of solder balls 13 disposed on the contacts 100, for an electronic device (not shown), such as a circuit board, to be mounted thereon.

In the semiconductor packaging structure 1, since the holes 140a of the encapsulation compound 14 are formed by burning and penetrating the encapsulation compound 14 with laser, the semiconductor packaging structure 1 thus has a high cost. Compound shreds will be generated in the holes 140a when the laser burns the encapsulation compound 14. As a result, the solder balls 13 cannot be bonded to the contacts 100 effectively, and are likely to be separated from the contacts 100, thereby causing the problem of low solder balls placement yield.

Therefore, how to solve the problems of the prior art is becoming an urgent issue in the art.

### SUMMARY

In view of the problems of the prior art, the present disclosure provides an electronic structure, comprising: a carrier; at least one electronic component mounted on and electrically connected to the carrier; a plurality of conductive elements bonded onto the carrier; and an encapsulation layer formed on the carrier, encapsulating the electronic component, and having a plurality of concave portions corresponding in position to the plurality of conductive elements for the plurality of conductive elements to be received therein, respectively, each of the concave portions having a substantially circular arc-shaped wall surface, wherein each of the plurality of conductive elements has a protruding portion protruding from an outer surface of the encapsulation layer and is in contact with or in no contact with corresponding one of the concave portions.

The present disclosure also provides a method for fabricating an electronic structure, comprising: disposing at least one electronic component on a carrier and electrically connecting the electronic component to the carrier; forming a plurality of conductive elements on the carrier; forming on the carrier an encapsulation layer that encapsulates the electronic component and the plurality of conductive elements; removing a portion of the encapsulation layer and a portion of the plurality of conductive elements to expose one end of each of the plurality of conductive elements from the encapsulation layer; and performing a reflow process, such that each of the plurality of conductive elements has a protruding portion protruding from an outer surface of the encapsulation layer, the encapsulation layer has a plurality of concave portions corresponding in position to the plurality of conductive elements, respectively, each of the plurality of conductive elements is in contact with or in no contact with corresponding one of the concave portions, and each of the plurality of concave portions has a substantially circular arc-shaped wall surface.

In an embodiment, the carrier has a first side and a second side opposing the first side, and the encapsulation layer and the plurality of conductive elements are disposed on the first side and/or the second side.

In an embodiment, the conductive elements are in partial contact with or in no contact with the encapsulation layer.

In an embodiment, the wall surface of each of the concave portions is substantially ball-shaped.

In an embodiment, each of the concave portions at an outer edge of the encapsulation layer is in the shape of an undercut.

In an embodiment, the method further comprises bonding a circuit board or a packaging structure to the protruding portions of the plurality of conductive elements.

In an embodiment, the method further comprises, prior to performing the reflow process, forming a groove on an end surface of each of the conductive elements exposed from the encapsulation layer. In another embodiment, the groove extends outward from the wall surface of the concave portion. In yet another embodiment, the groove is integrated with corresponding one of the concave portions. In still another embodiment, the groove has an oblique wall surface.

In an embodiment, the method further comprises, prior to performing the reflow process, forming a conductive material on an end surface of each of the conductive elements exposed from the encapsulation layer.

It is known from the above that in the electronic structure and the method for fabricating the same according to the present disclosure, the end surfaces of the conductive elements are exposed from the encapsulation layer, the reflow process is performed, and a cohesive force of the conductive elements forces the protruding portions to be formed on the conductive elements and exposed from the encapsulation layer, allowing an external electronic device to be mounted thereon. Therefore, the electronic structure is fabricated in a simple way with reduced costs, as compared with the laser process used in the prior art, and the conductive elements will not be separated from solder balls bonded thereto.

### BRIEF DESCRIPTION OF THE DRAWINGS

FIG. 1 is a cross-sectional view of a semiconductor packaging structure according to the prior art.

FIGS. 2A to 2E are cross-sectional views illustrating a method for fabricating an electronic structure of a first embodiment according to the present disclosure.

FIG. 2A′ is a schematic diagram of another aspect of FIG. 2A.

FIG. 2D′ is a locally enlarged view of FIG. 2D.

FIG. 2D″ is a schematic diagram of another aspect of FIG. 2D′.

FIG. 2F is a cross-sectional view of an electronic structure of another aspect according to the present disclosure.

FIG. 3 is a cross-sectional view of an electronic structure of another embodiment according to the present disclosure.

FIG. 4 is a cross-sectional view of an electronic structure of yet another embodiment according to the present disclosure.

FIG. 5A is a cross-sectional view of an electronic structure of still another embodiment according to the present disclosure.

FIG. 5B is a schematic diagram of another application aspect of FIG. 5A.

FIGS. 6A to 6C are cross-sectional views illustrating a method for fabricating an electronic structure of a second embodiment according to the present disclosure.

FIG. 6B′ is a schematic diagram of another embodiment of FIG. 6B.

FIG. 6B″ is a schematic diagram of another embodiment of FIG. 6B′.

FIG. 6C′ is a schematic diagram of a subsequent process of FIG. 6B′.

FIG. 6C″ is a schematic diagram of another aspect of FIG. 6C′.

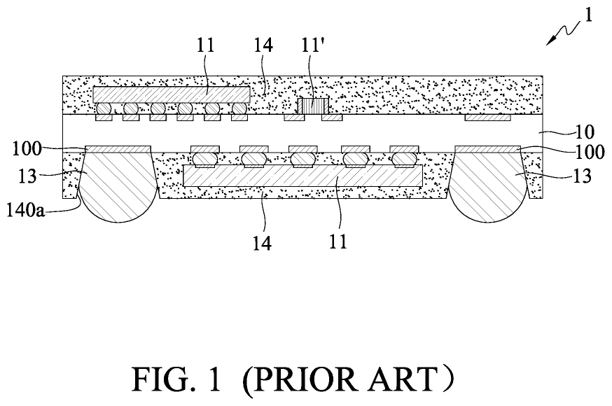

### DETAILED DESCRIPTION

The following illustrative embodiments are provided to illustrate the present disclosure, these and other advantages and effects can be apparently understood by those in the art after reading the disclosure of this specification. The present disclosure can also be performed or applied by other different embodiments. The details of the specification may be on the basis of different points and applications, and numerous modifications and variations can be devised without departing from the spirit of the present disclosure.

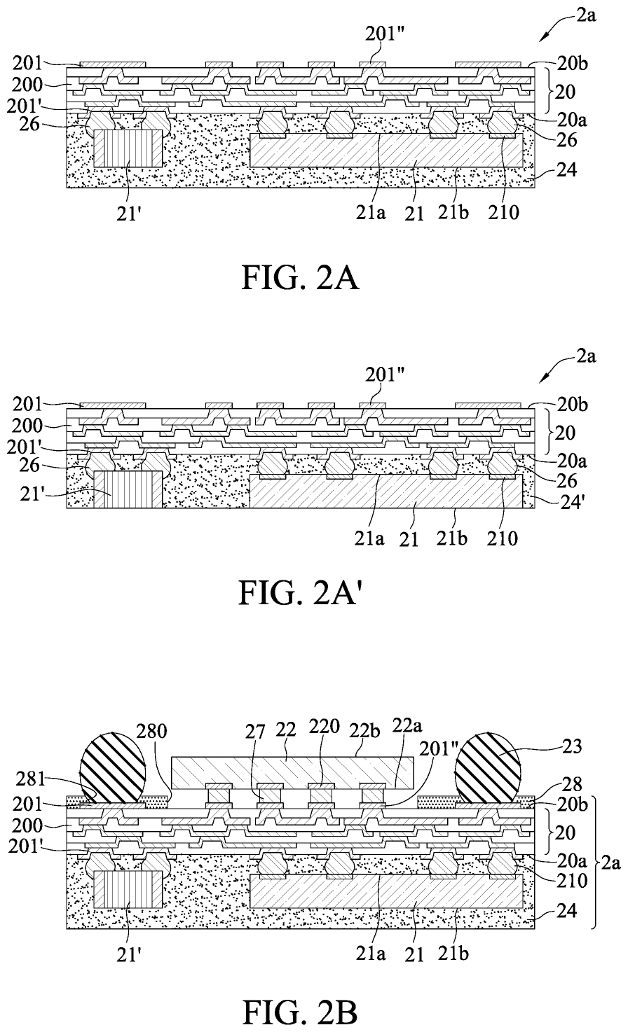

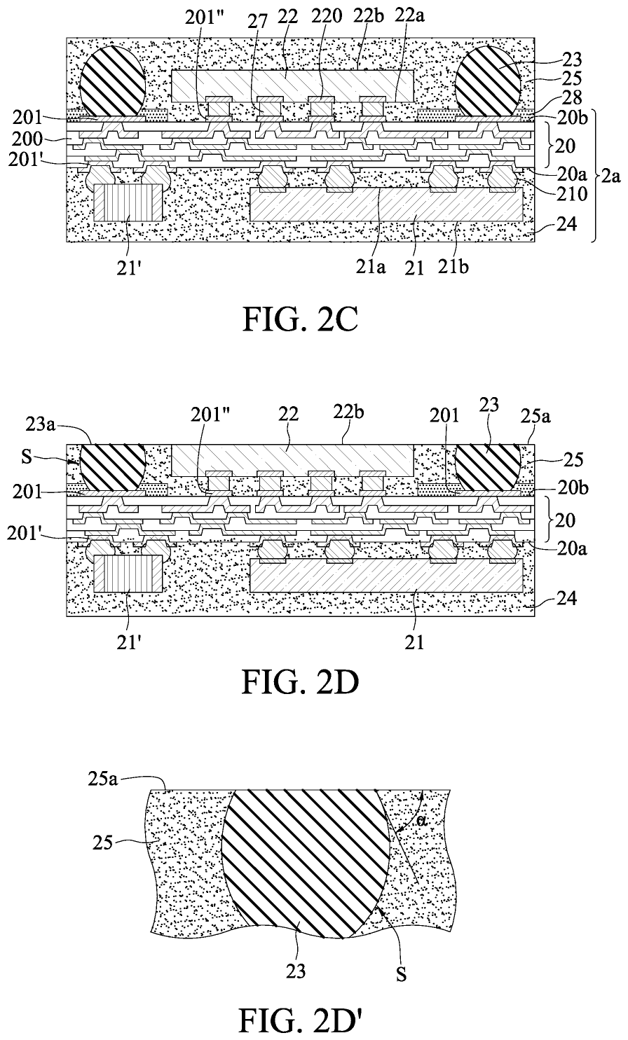

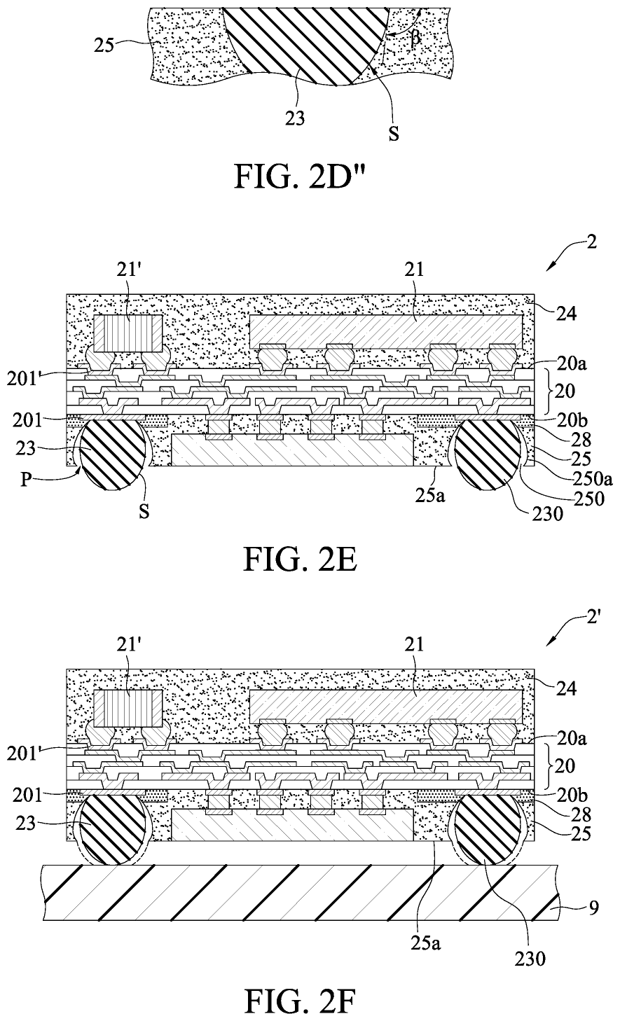

FIGS. 2A to 2E are cross-sectional views illustrating a method for fabricating an electronic structure 2 of a first embodiment according to the present disclosure.

As shown in FIG. 2A, an electronic component 2a is provided that includes a carrier 20, at least one first side electronic component 21, 21′, and a molding compound layer 24.

In an embodiment, the electronic component 2a is fabricated in any method.

The carrier 20 has a first side 20a and a second side 20b opposing the first side 20a. In an embodiment, the carrier 20 is a packaging substrate having a core layer and a circuit structure or a coreless circuit structure. The carrier 20 comprises at least one dielectric layer 200 and a circuit layer 201, 201′, 201″ bonded to the dielectric layer 200. In an embodiment, a coreless circuit structure is fabricated in a redistribution layer (RDL) fabrication method. In an embodiment, the circuit layer 201, 201′, 201″ is made of copper. In another embodiment, the dielectric layer 200 is made of polybenzoxazole (PBO), polyimide (PI), prepreg (PP) etc. In yet another embodiment, the carrier 20 is a carrying unit, such as a silicon interposer, and is configured for carrying an electronic component, such as a chip.

The first side electronic component 21, 21′ is bonded to the first side 20a of the carrier 20. In an embodiment, the first side electronic component 21, 21′ is an active element, such as a semiconductor chip, a passive element, such as a resistor, an inductor or a capacitor, or a combination thereof. In an embodiment, the first side electronic component 21 is a semiconductor chip and has an active surface 21a and an inactive surface 21b opposing the active surface 21a. A plurality of electrode pads 210 are disposed on the active surface 21a and electrically connected to the circuit layer 201′ in a flip-chip manner (e.g., via conductive bumps 26 shown in the figure). In another embodiment, the first side electronic component 21 is electrically connected to the circuit layer 201′ via a plurality of solder wires (not shown) in a wire bonding manner. In yet another embodiment, the first side electronic component 21 is in direct contact with the circuit layer 201′. In still another embodiment, the first side electronic component 21′ is a passive element and electrically connected to the circuit layer 201′ via conductive bumps 26. In further another embodiment, the first side electronic component 21, 21′ is electrically connected to circuit layer in other manners.

The molding compound layer 24 is formed on the first side 20a of the carrier 20 and encapsulates the first side electronic component 21, 21′. In an embodiment, the molding compound layer 24 is made of an insulation material, such as polyimide (PI), a dry film, epoxy, an encapsulation compound and a molding compound by lamination or molding.

The molding compound layer 24 covers the inactive surface 21b of the first side electronic component 21. As shown in FIG. 2A′, an outer surface of the molding compound layer 24′ is flush with the inactive surface 21b of the first side electronic component 21, and the inactive surface 21b of the first side electronic component 21 is exposed from the molding compound layer 24′.

As shown in FIG. 2B, at least one second side electronic component 22 is disposed on the second side 20b of the carrier 20, and a plurality of conductive elements 23 are disposed on the circuit layer 201 on the second side 20b of the carrier 20.

In an embodiment, the second side electronic component 22 is an active element, such as a semiconductor chip, a passive element, such as a resistor, an inductor or a capacitor, or a combination thereof. In an embodiment the second side electronic component 22 is a semiconductor chip, and has an active surface 22a and an inactive surface 22b opposing the active surface 22a. The active surface 22a has a plurality of electrode pads 220. The second side electronic component 22 is electrically connected to the circuit layer 201″ in a flip-chip manner (via conductive bumps 27 shown in the figure) via the electrode pads 220. In another embodiment, the second side electronic component 22 is electrically connected to the circuit layer 201″ via a plurality of solder wires (not shown) in a wire bonding manner. In yet another embodiment, the second side electronic component 22 is in direct contact with the circuit layer 201″. In still another embodiment, the second side electronic component 22 is electrically connected to the circuit layer in other manners.

In an embodiment, a non-metal material, such as a solder resist layer (e.g., solder mask), an underfill or a combination thereof, is first formed on the second side 20b of the carrier 20 to act as a protection layer 28, a portion of the protection layer 28 is then removed to form an opening 280 that is exposed from a portion of the second side 20b of the carrier 20, and the second side electronic component 22 is disposed in the opening 280 and electrically connected to the circuit layer 201″. In another embodiment, the protection layer 28 is patterned, molded and formed on a portion of the circuit layer 201 on the second side 20b of the carrier 20 with a portion of the second side 20b of the carrier 20 being exposed.

In an embodiment, the conductive elements 23 are made of a solder tin material, are in the shape of balls, and have continuous ball surfaces S (e.g., circular arc-shaped) on outer surfaces thereof. In an embodiment, a plurality of holes 281 are formed on the protection layer 28, to allow a portion of the circuit layer 201 on the second side 20b of the carrier 20 to be exposed therefrom, and the conductive elements 23 are bonded (e.g., fused) and electrically connected to the circuit layer 201 in the holes 281 via a ball placement process.

In an embodiment, the active surface 21a of the first side electronic component 21 faces the active surface 22a of the second side electronic component 22.

As shown in FIG. 2C, an encapsulation layer 25 is formed on the second side 20b of the carrier 20 and encapsulates the second side electronic component 22, the conductive elements 23, the conductive bumps 27 and the protection layer 28.

In an embodiment, the encapsulation layer 25 is made of an insulation material, such as PI, a dry film, epoxy, epoxy of an encapsulation compound or a molding compound by lamination or molding and formed on the second side 20b of the carrier 20. In another embodiment, the encapsulation layer 25 and the protection layer 28 are made of different materials.

In an embodiment, the encapsulation layer 25 and the molding compound layer 24 are made of the same, or different materials.

As shown in FIG. 2D, a leveling process, such as a grinding process, is performed to remove a portion of the encapsulation layer 25 and a portion of the conductive elements 23, such that the upper surface 25a of the encapsulation layer 25 is flush with the end surfaces 23a of the conductive elements 23 and the conductive elements 23 are exposed from the surface 25a of the encapsulation layer 25.

In an embodiment, the conductive elements 23 have continuous ball-shaped surfaces S, and an intersection surface between the encapsulation layer 25 and the conductive elements 23 also has a continuous ball-shaped surface S (e.g., circular arc-shaped surface).

In an embodiment, the upper surface 25a of the encapsulation layer 25 is flush with the inactive surface 22b of the second side electronic component 22, and the inactive surface 22b of the second side electronic component 22 is exposed from the encapsulation layer 25.

As shown in FIG. 2E, a heating process, such as a reflow process, is performed. Through the continuous ball-shaped surfaces S of the conductive elements 23, a cohesive force of the conductive elements 23 (a solder tin material) forces the conductive elements 23 embedded in the encapsulation layer 25 to shrink inward and protrude outward from the surface 25a of the encapsulation layer 25, and protruding portions 230 are thus formed. A gap P is formed between the conductive elements 23 and the encapsulation layer 25 (i.e., the encapsulation layer 25, which is in close contact with the conductive elements 23 originally, has concave portions 250 having wall surfaces 250a since the conductive elements 23 shrink inward, and the wall surfaces 250a have continuous ball-shaped surfaces S, as that of the conductive elements 23 before shrinking inward), so that the electronic structure 2 according to the present disclosure is formed.

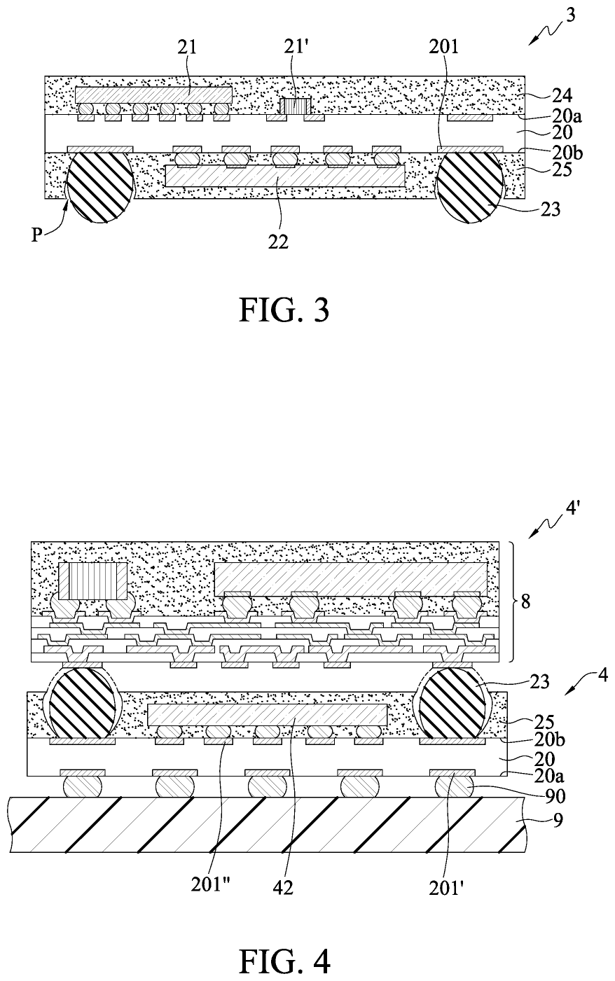

The size of the gap P can be controlled by controlling the time, temperature, etc. of the reflow process, such that the conductive elements 23 are in no contact with the encapsulation layer 25 (e.g., the electronic structure 2 shown in FIG. 2E) or are in partial contact with the encapsulation layer 25 (e.g., the electronic structure 3 shown in FIG. 3) to strengthen the stability and reliability of the positioning of the conductive elements 23.

Subsequently, a circuit board 9 (e.g., a mother board) shown in FIG. 2F, a packaging structure or an electronic device of another structure (e.g., another chip) can be mounted in a reflow method via the conductive elements 23, to form another electronic structure 2′. In an embodiment, after another electronic device is mounted on the electronic structure 2, the gap P may be filled completely and disappeared (as indicated by a dashed line shown in FIG. 2F) because of the reflow process and the added tin of the another electronic device.

In the method for fabricating an electronic structure according to the present disclosure, an intersection surface between the encapsulation layer 25 and the conductive elements 23 has a continuous ball-shaped surface S, and the end surfaces 23a of the conductive elements 23 are exposed from the encapsulation layer 25. After a heating process, such as a reflow process, is performed, a cohesive force of the conductive elements 23 forces protruding portions 230 protruding from the surface 25a of the encapsulation layer 25 to be formed on the conductive elements 23 for mounting an external electronic device. The cohesive force also forces the conductive elements 23 to shrink inward and concave portions 250 to be formed between the conductive elements 23 and the encapsulation layer 25. The cross-section of the wall surface 250a of the concave portion 250 in a top-to-bottom direction is substantially circular arc-shaped (continuous ball-shaped surface S), and a solder climbing distance from neighboring solder balls can be extended effectively. Therefore, a bridge connection problem is solved when the electronic structure 2 is mounted via the conductive elements 23 on an external electronic device.

In an embodiment, a portion of the continuous ball-shaped surface S close to the surface 25a of the encapsulation layer 25 is in the shape of an undercut (as shown in FIG. 2D′, an edge angle α is less than or equal to 90 degrees). The undercut can effectively secure a flux used for cleaning and wetting the conductive elements 23 in a reflow process, allowing the flux to clean and wet the conductive elements 23 efficiently. Compared with the prior art, which uses laser to form the holes, the method for fabricating an electronic structure according to the present disclosure will not generate compound shreds of the encapsulation layer 25, and thus the conductive elements 23 can be bonded to the circuit layer 201 securely and thereby preventing a ball-falling situation.

When the leveling process (e.g., a grinding process shown in FIG. 2D) is performed, the amount of the encapsulation layer 25 and the conductive elements 23 removed can be adjusted, such that an edge angle β of the continuous ball-shaped surfaces S of the conductive elements 23 close to the surface 25a of the encapsulation layer 25 is greater than or equal to 90 degrees, as shown in FIG. 2D″.

In an embodiment, an electronic component is disposed on at least one of the first side 20a and the second side 20b of the carrier 20. In an electronic structure 4 shown in FIG. 4, at least one electronic component 42 is disposed on either the first side 20a or the second side 20b of the carrier 20. In an embodiment, the electronic component 42 is bonded onto the second side 20b of the carrier 20. In another embodiment, the electronic component 42 is an active element, such as a semiconductor chip, a passive element, such as a resistor, an inductor or a capacitor, or a combination thereof. In an embodiment, the electronic component 42 is a semiconductor chip, and is electrically connected to the circuit layer 201″ in a flip-chip manner or other manners. In another embodiment, an electronic device, such as another package 8 or a chip, is mounted on the electronic structure 4 via the conductive elements 23, and another electronic device, such as a circuit board 9, is mounted through the circuit layer 201′ on the first side 20a of the carrier 20 via a plurality of solder materials 90, to form another electronic structure 4′. In an embodiment, as another electronic device is mounted on the electronic structure 4, the gap P may be filled completely and disappeared (as indicated by a dashed line shown in FIG. 4) because of the reflow process or the added tin of the another electronic device.

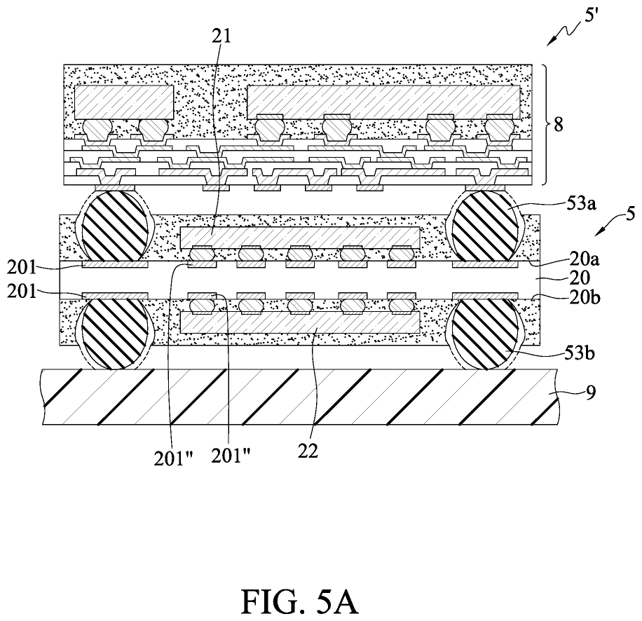

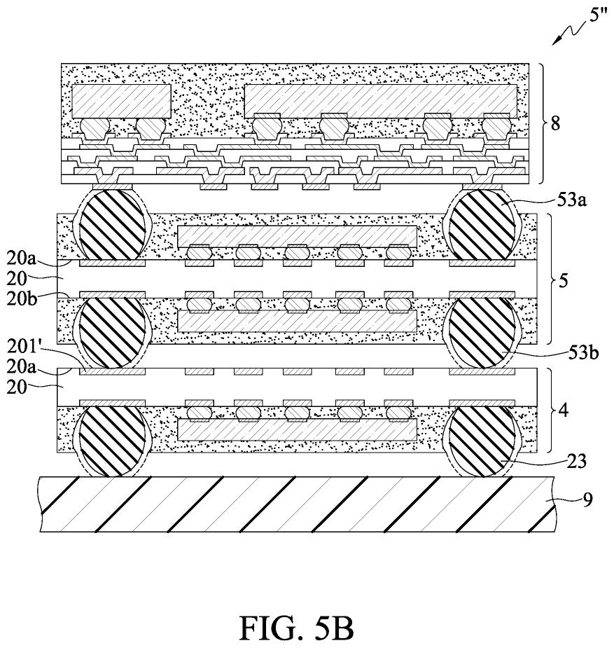

In an embodiment, conductive elements are disposed on at least one of the first side 20a and the second side 20b of the carrier 20. In an electronic structure 5 shown in FIG. 5A, first conductive elements 53a and second conductive elements 53b are disposed on the first side 20a and the second side 20b of the carrier 20, respectively, an electronic device, such as another package 8 or a chip, is mounted on the electronic structure 5 via the first conductive elements 53a, and another electronic device, such as a circuit board 9, is mounted via the second conductive elements 53b, to form another electronic structure 5′. In an embodiment, as another electronic device is mounted on the electronic structure 5, the gap P may be filled completely and disappeared (as indicated by a dashed line shown in FIG. 5A) because of the reflow process or the added tin of the another electronic device.

In an embodiment, two of the electronic structures fabricated according to the present disclosure are stacked, as shown in FIG. 5B. The second conductive elements 53b of the electronic structure 5 shown in FIG. 5A are stacked on the circuit layer 201′ on the first side 20a of the carrier 20 of the electronic structure 4 shown in FIG. 4, and the conductive elements 23 of the electronic structure 4 are mounted to an electronic device, such as the circuit board 9, to form another electronic structure 5″. In an embodiment, as another electronic device is mounted on the electronic structure 4, 5, the gap P may be filled completely and disappeared (as indicated by a dashed line shown in FIG. 5B) because of the reflow process or the added tin of the another electronic device.

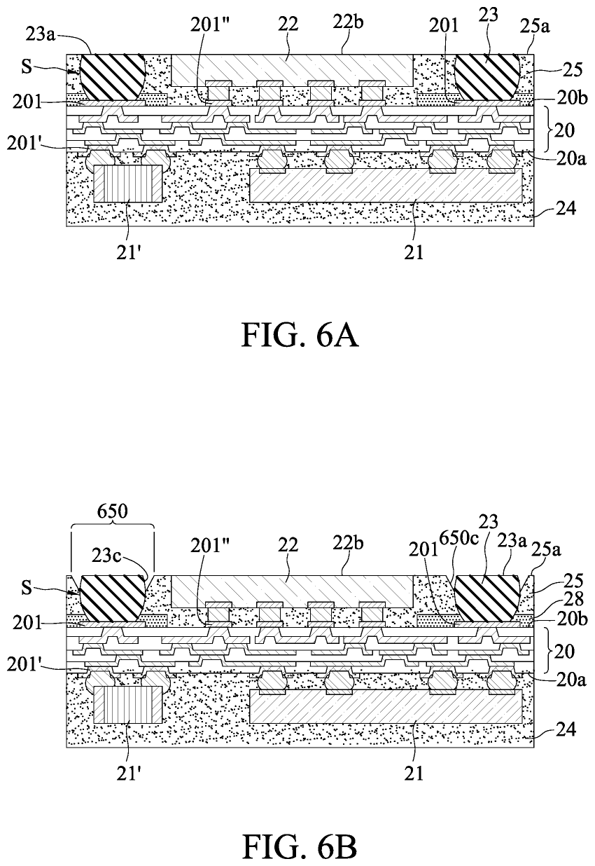

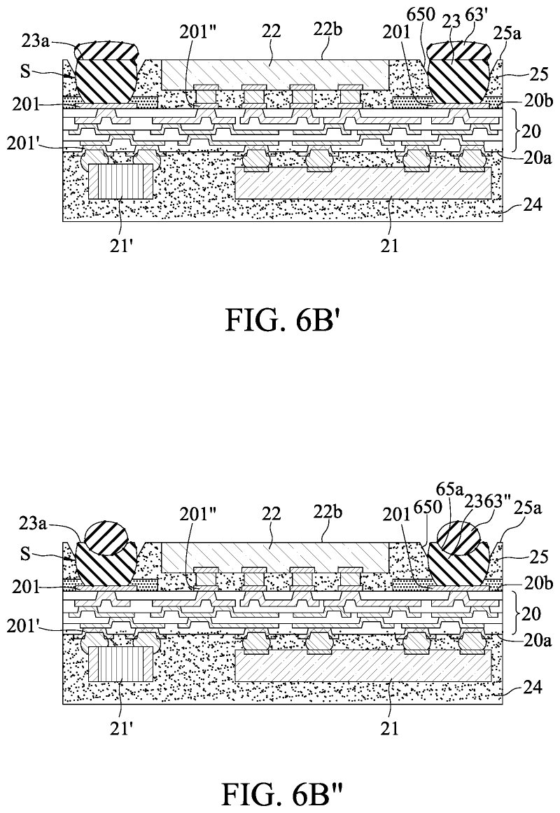

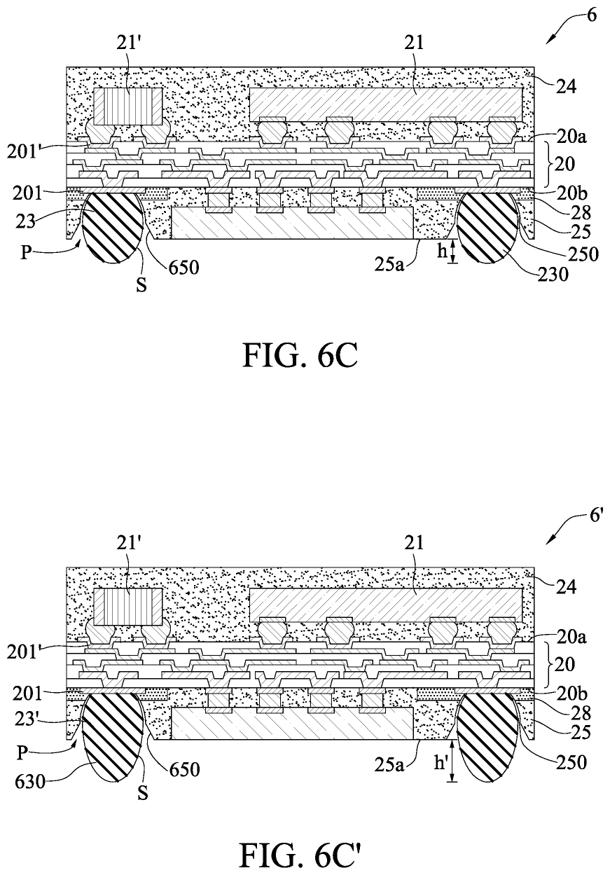

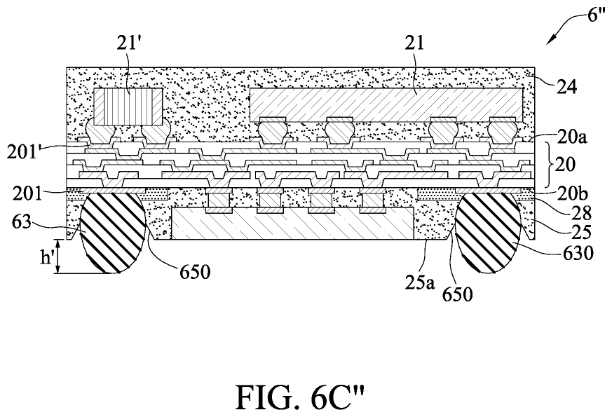

FIGS. 6A to 6C are cross-sectional views illustrating a method for fabricating an electronic structure 6 of a second embodiment according to the present disclosure. The second embodiment differs from the first embodiment in that grooves are further formed in the second embodiment, which will be described in the following paragraphs.

As shown in FIG. 6A, the leveling process shown in FIG. 2D is complete, such that the upper surface 25a of the encapsulation layer 25 is flush with the end surfaces 23a of the conductive elements 23, and the conductive elements 23 are exposed from the surfaces 25a of the encapsulation layer 25.

As shown in FIG. 6B, grooves 650 corresponding to the end surfaces 23a of the conductive elements 23, respectively, are formed on the upper surface 25a of the encapsulation layer 25.

In an embodiment, the edge of the end surface 23a of the conductive elements 23 is burned by laser to form the groove 650, and a portion of a peripheral surface 23c of the conductive elements 23 is exposed from the groove 650. In an embodiment, the groove 650 does not extend to a surface of the protection layer 28 on the second side 20b of the carrier 20, so that the entire peripheral surface 23c of the conductive elements 23 will not be exposed from the groove 650. In another embodiment, the groove 650 has a flat, straight and oblique wall surface 650c, such that the wall surface 650c is in not contact with the peripheral surface 23c of the conductive elements 23.

In an embodiment, at least one conductive material 63′, 63″, such as a tin paste conductive material 63′ shown in FIG. 6B′ or a solder ball conductive material 63″ shown in FIG. 6B″, is formed within a concave slot 65a formed on the end surfaces 23a of the conductive elements 23.

As shown in FIG. 6C, a heating process, such as a reflow process, is performed subsequent to the process shown in FIG. 6B. Through the continuous ball-shaped surfaces S of the conductive elements 23, a cohesive force of the conductive elements 23 forces the conductive elements 23 embedded in the encapsulation layer 25 to shrink inward, and forces protruding portions 230 protruding from the surface 25a of the encapsulation layer 25. A gap P (i.e., at the concave portion 250) is formed between the conductive elements 23 and the encapsulation layer 25, and an electronic structure 6 according to the present disclosure is thus formed.

Following the processes shown in FIG. 6B′ or FIG. 6B″, the reflow process can be controlled by controlling the time, temperature, etc. and the size of the gap P is thus controlled accordingly, such that the gap P is still formed between the conductive elements 23′ and the encapsulation layer 25, e.g., the electronic structure 6′ shown in FIG. 6C′. In another embodiment, the gap P is not formed between the conductive elements 63 and the encapsulation layer 25, e.g., the electronic structure 6″ shown in FIG. 6C″, in which the gap P disappears.

When the circuit board 9 or other electronic device is mounted on the conductive elements 23, 23′, melt solder balls can be received in the groove 650, so as to prevent two neighboring conductive elements 23 and 23′ from being bridged to each other.

In an embodiment, the height h of the protruding portions 230 of the conductive elements 23 is not sufficiently great (as shown in FIG. 6C), a conductive material 63′, 63″ can be added, such that the conductive elements 23′, 63 have protruding portions 630 that meet the height h′ requirement after the reflow process (as shown in FIGS. 6C′ and 6C″). The present disclosure further provides an electronic structure 2, 3, 4, 5, 6, 6′, 6″, which comprises a carrier 20, at least one electronic component 42 (or a first side electronic component 21, 21′ and a second side electronic component 22), a plurality of conductive elements 23, 23′, 63 (or first conductive elements 53a and second conductive elements 53b), and an encapsulation layer 25 (the molding compound layer 24 can act as the encapsulation layer 25).

The carrier 20 has a first side 20a and a second side 20b opposing the first side 20a. At least one circuit layer 201, 201′, 201″ is disposed on the carrier 20.

The electronic component 42 (or the first side electronic component 21, 21′ and the second side electronic component 22) is disposed on the first side 20a and/or the second side 20b of the carrier 20 and electrically connected to the circuit layer 201′, 201″.

The conductive elements 23, 23′, 63 (or the first conductive elements 53a and the second conductive elements 53b) are bonded onto the circuit layer 201.

The encapsulation layer 25 is formed on the carrier 20 and encapsulates the electronic component 42 (or the second side electronic component 22). The protruding portions 230, 630 of the conductive elements 23, 23′, 63 (or the first conductive elements 53a and the second conductive elements 53b) are exposed from the encapsulation layer 25. A gap P or no gap P is formed between the conductive elements 23, 23′, 63 and the encapsulation layer 25.

In an embodiment, the encapsulation layer 25 has concave portions 250, and the conductive elements 23 (or the first conductive elements 53a and the second conductive elements 53b) are disposed in the concave portions 250, respectively. A gap P is formed between the wall surfaces 250a of the concave portion 250 and the conductive elements 23, 23′ (or the first conductive elements 53a and the second conductive elements 53b), and the conductive elements 23, 23′ can be in partial contact with or in no contact with the wall surfaces 250a of the concave portions 250. In an embodiment, the concave portions 250 have edges in the shape of an undercut.

In an embodiment, the wall surface 250a of the concave portion 250 extends outward to form a groove 650. In an embodiment, the groove 650 has an oblique wall surface 650c.

In an electronic structure and a method for fabricating the same according to the present disclosure, the end surfaces of the conductive elements are exposed from the encapsulation layer. After a reflow process is performed, a cohesive force of the conductive elements forces the conductive elements to protrude to have protruding portions exposed from the encapsulation layer, allowing an external electronic device to be mounted thereon. The conductive elements shrink inward, and concave portions are formed between the conductive elements and the encapsulation layer. The concave portions have circular arc-shaped wall surfaces, and a solder climbing distance from neighboring solder balls is extended effectively. As a result, a bridging connection problem can be avoided when an external electronic device is mounted via the conductive elements on the electronic structure. Therefore, the electronic structure is fabricated in a simple way with reduced cost, as compared with the laser process used in the prior art, and the conductive elements will not be separated from solder balls bonded thereto.

The foregoing descriptions of the detailed embodiments are illustrated to disclose the features and functions of the present disclosure and not restrictive of the scope of the present disclosure. It should be understood to those in the art that all modifications and variations according to the spirit and principle in the present disclosure should fall within the scope of the appended claims.

1-8. (canceled)

9: A method for fabricating an electronic structure, comprising:
disposing at least one electronic component on a carrier and electrically connecting the electronic component to the carrier;
forming a plurality of conductive elements on the carrier;
forming on the carrier an encapsulation layer encapsulating the electronic component and the plurality of conductive elements;
removing a portion of the encapsulation layer and a portion of the plurality of conductive elements to expose one end of each of the plurality of conductive elements from the encapsulation layer;
forming grooves corresponding to end surfaces of the conductive elements, respectively, on a surface of the encapsulation layer;
forming a concave slot on the end surface of each of the conductive elements;
forming a conductive material within the concave slot on the end surface of each of the conductive elements exposed from the encapsulation layer; and
after forming the conductive material within the concave slot, performing a reflow process, such that each of the plurality of conductive elements has a protruding portion protruding from an outer surface of the encapsulation layer, the encapsulation layer has a plurality of concave portions corresponding in position to the plurality of conductive elements, respectively, each of the plurality of conductive elements is in contact with or in no contact with corresponding one of the concave portions, and each of the plurality of the concave portions has a substantially circular arc-shaped wall surface.

10: The method of claim 9, wherein the carrier has a first side and a second side opposing the first side, and the encapsulation layer and the plurality of conductive elements are disposed on the first side and/or the second side.

11: The method of claim 9, wherein the conductive elements are in partial contact with or in no contact with the encapsulation layer.

12: The method of claim 9, wherein the wall surface of each of the concave portions is substantially ball-shaped.

13: The method of claim 9, wherein each of the concave portions at an outer edge of the encapsulation layer is in a shape of an undercut.

14: The method of claim 9, further comprising bonding a circuit board or a packaging structure to the protruding portions of the plurality of conductive elements.

15. (canceled)

16: The method of claim 9, wherein the groove is integrated with corresponding one of the concave portions.

17: The method of claim 9, wherein the groove has an oblique wall surface.

18. (canceled)
